(19) United States
(12) Patent Application Publication
(10) Pub. No.: US 2008/0237814 A1
(43) Pub. Date: Oct. 2, 2008

(54) ISOLATED SOLDER PADS

(75) Inventor: Jaime A. Bayan, Palo Alto, CA (US)

Correspondence Address: Beyer Law Group LLP, P.O. BOX 1687, Cupertino, CA, 95015-1687, US

(73) Assignee: National Semiconductor Corporation

(21) Appl. No.: 11/691,429

(22) Filed: Mar. 26, 2007

(51) Int. Cl. H01L 23/495

(52) U.S. Cl. 257/666

(57) ABSTRACT

An integrated circuit package is described that includes a die and a lead frame that includes recessed regions for preventing the undesired spread of solder during reflow. The die includes a plurality of solder bumps formed on its active surface. The lead frame includes a plurality of leads, each having an associated solder pad. Each solder pad is suitably positioned adjacent and electrically contacting an associated solder bump on the die. Each lead also includes a recessed region in a region adjacent to the solder pad. The recessed region serves to isolate the surface of the solder pad from the other surfaces of the lead. In this manner, the solder of the solder bump that contacts the lead is confined to the surface of the associated solder pad.

### BRIEF DESCRIPTION OF THE INVENTION

The present invention generally relates to the packaging of integrated circuits (ICs). More particularly, a lead frame suitable for use in packaging solder bumped dice is described that limits the undesired spread of solder.

### BACKGROUND OF THE INVENTION

There are a number of conventional processes for packaging integrated circuits. Many packaging techniques use a lead frame that has been stamped or etched from a metal (typically copper) sheet to provide electrical interconnects to external devices. One package style utilizing a lead frame is a flip-chip-on-lead (FCOL) package.

Two examples of representative FCOL packages 100 and 100′ will now be described with reference to FIGS. 1A-B. A lead frame suitable for use in an FCOL package generally includes a plurality of leads 108. During electrical connection to an individual die 116, contact regions 112 on the leads 108 are soldered to I/O pads on the active surface of the associated die. The I/O pads may be bond pads on the face of the die 116 or contact pads that have been redistributed from the bond pads using conventional redistribution techniques. To facilitate electrical connection, underbump metallization (UBMs) may be formed on the I/O pads. In general, solder bumps 122 are formed on the I/O pads 118 or underbump metallization. Both underbump metallization as well as solder bumping may be, and preferably are, performed at the wafer level prior to individual die singulation.

Flux is generally applied to the solder bumps 122 and/or contact regions 112 of the leads 108. Flux facilitates soldering by chemically cleaning the metals to be joined. More particularly, flux may remove and prevent further oxidation of the metals where the flux is applied. Secondarily, flux acts as a wetting agent to facilitate the spread of solder during soldering processes. After flux application, the die 116 and lead frame are generally placed in an oven for reflow. During reflow, the solder bumps 122 are melted. The liquid solder spreads along the contact regions 112 and underbump metallization stacks (or bond pads) and, upon cooling, solidifies and joins the leads 108 to the die 116. Generally, portions of the die and lead frame are then encapsulated and singulated leaving opposite ends of the leads (relative to the contact regions 112) exposed to facilitate electrical connection to external devices.

One of the challenges encountered in FCOL packaging is preventing excessive solder ball collapse during reflow due to the solder spreading too far along the lead 108. The undesired spread of solder may lead to reliability problems. More particularly, as the solder spreads, the shape of the solder joint connection may become distorted from the desired shape. As a consequence, the structural integrity of the solder joint connection may be weakened. Furthermore, the distortion may also result in a non-uniform standoff height and/or a reduced standoff height between the leads 108 and the die 116. Standoff height is generally a very relevant concern in packaging FCOL packages. In general, the standoff height between the bond pad and contact region 112 will be a function of the volume of solder in the solder bump 122 as well as the surface areas and geometries of the associated bond pad (or UBM) and contact region 112. It is thus desirable to confine the solder to defined contact regions on the leads 108.

### SUMMARY OF THE INVENTION

In one embodiment, an integrated circuit package is described that includes a die, a lead frame, and an encapsulant material. The die includes a plurality of I/O pads formed on an active surface of the die. The lead frame includes a multiplicity of leads. A plurality of the leads each have at least one associated solder pad. Each solder pad is positioned so as to mirror an associated I/O pad on the die. The lead also includes a recessed region in a region adjacent to the solder pad. The recessed region serves to isolate the surface of the solder pad from the other surfaces of the lead. The package additionally includes a plurality of solder bumps. Each solder bump is arranged to electrically connect an associated I/O pad on the die to an associated solder pad on the lead frame. In this manner, the solder of the solder bump that contacts the lead is confined to the surface of the associated solder pad. Additionally, an encapsulant material encapsulates the solder bumps and at least portions of the die and leads.

In another embodiment, a lead frame panel suitable for use in semiconductor packaging is described. The lead frame panel includes a matrix of tie bars that define a plurality of device areas that are each configured suitably to support an associated solder bumped die. Each device area of the lead frame panel includes a multiplicity of leads. A plurality of the leads each have at least one associated solder pad. Each solder pad is suitably positioned so as to overlap the corresponding I/O pad on a die. The lead also includes a recessed region in a region adjacent to the solder pad. The recessed region serves to isolate the surface of the solder pad from the other surfaces of the lead. In this manner, solder of a solder bump on an I/O pad on the die that contacts the lead is confined to the surface of the associated solder pad when the solder is melted during reflow.

### BRIEF DESCRIPTION OF THE DRAWINGS

For a better understanding of the invention, reference should be made to the following detailed description taken in conjunction with the accompanying drawings, in which:

FIGS. 1A-B illustrate representative FCOL packages;

FIGS. 2A-D illustrate diagrammatic top views of a lead frame panel suitable for packaging dice in accordance with an embodiment of the present invention; and

FIGS. 3A-3D illustrate diagrammatic side views of die packages utilizing a lead frame having recessed regions in accordance with an embodiment of the present invention.

FIG. 4 is a diagrammatic side view of a flip chip on lead (FCOL) package utilizing the lead frame illustrated in FIGS. 2C and 3A.

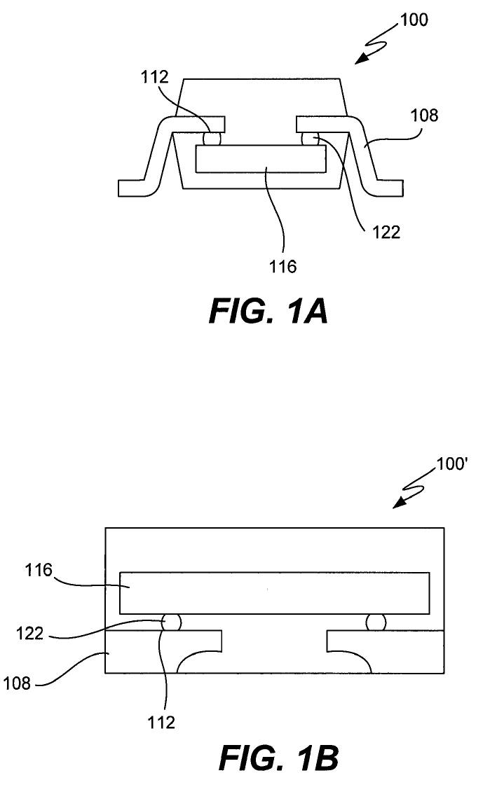

Like reference numerals may refer to corresponding parts throughout the drawings.

### DETAILED DESCRIPTION OF THE DRAWINGS

The present invention generally relates to the packaging of integrated circuits (ICs). More particularly, a lead frame suitable for use in packaging solder bumped dice is described that limits the undesired spread of solder.

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

The following description focuses on the packaging of flip-chip style dice utilizing lead frames. However, it is contemplated that the present invention may be advantageously practiced in the packaging of a variety of dice into a variety of package configurations in which solder bumps on the dice are to be directly electrically connected with metallic contacts on a substrate.

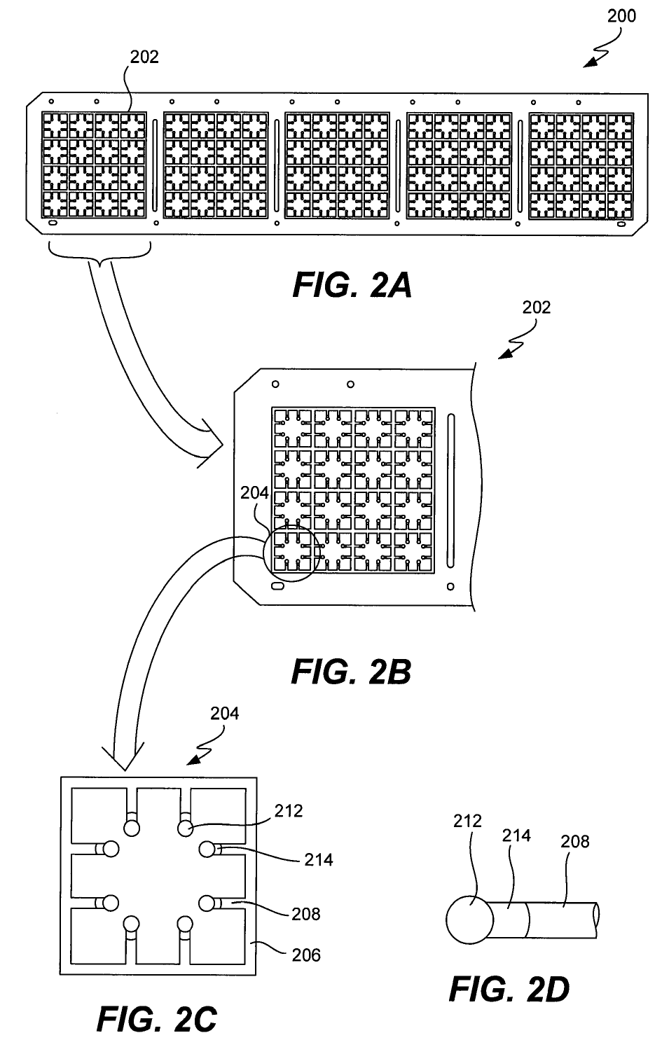

With reference to FIGS. 2-4, various embodiments of the present invention will be described that provide a lead frame having leads with isolated solder pads. Isolating each solder pad from the rest of the lead surface inhibits undesired spread of solder along the lead. Furthermore, controlling the volume of the solder as well as the surface area and geometry of the solder pads allows control over the resultant standoff height between the die and the leads of the lead frame.

FIGS. 2A-D illustrate a lead frame panel 200 suitable for use in packaging integrated circuits according to various embodiments of the present invention. FIG. 2A illustrates a diagrammatic top view of a lead frame panel 200 arranged in the form of a strip. The lead frame panel 200 can be configured as a metallic structure with a number of two-dimensional arrays 202 of device areas. As illustrated in the successively more detailed FIGS. 2B-C, each two-dimensional array 202 includes a plurality of device areas 204, each configured for use in a single IC package, and each connected by fine tie bars 206. During packaging, one or more semiconductor dice are affixed to each device area 204, where they may then be subjected to electrical connection, encapsulation and singulation processes, yielding individual IC packages.

In order to facilitate these processes, each device area 204 includes a plurality of leads 208, each supported at one end by the tie bars 206. As illustrated in FIG. 2D, the leads 208 include conductive solder pads 212 to provide conductive contact regions to electrically connect the leads to associated I/O pads 318 on a die 320. Although a specific lead frame panel 200 arrangement has been described and illustrated, the described invention may be applied to an extremely wide variety of other lead frame panels or strip configurations as well.

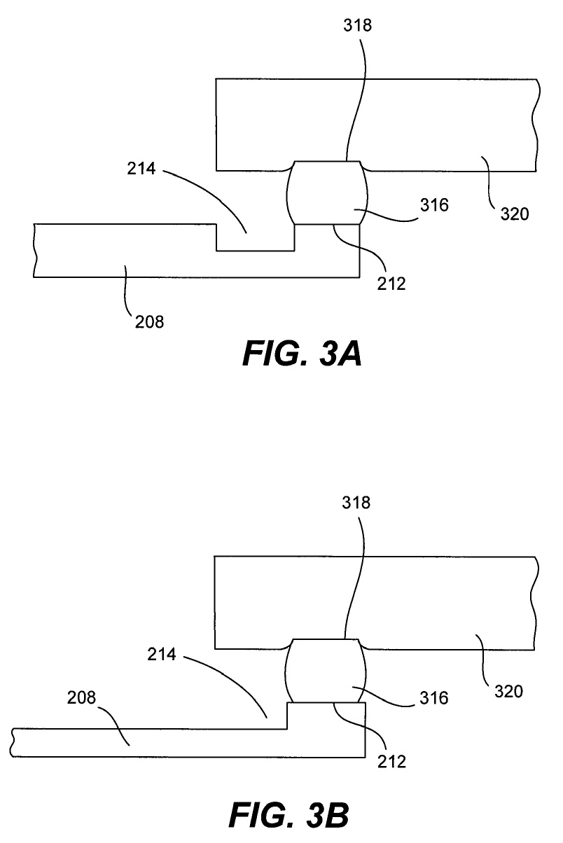

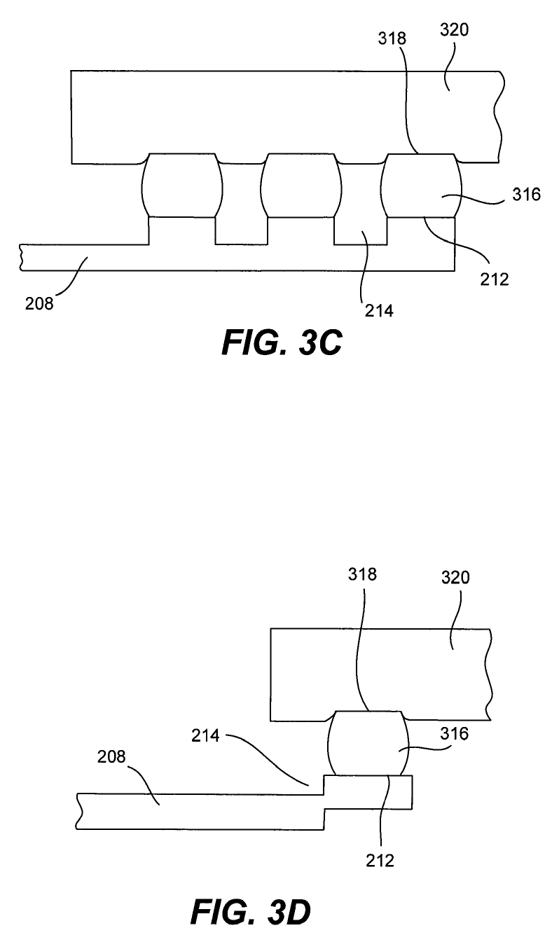

FIGS. 3A-D illustrate portions of individual device packages each utilizing a single lead frame device area 204 according to various embodiments of the present invention. Although FIGS. 2A-2D and 3A-3D are described as having solder pads 212 on a top surface of the lead frame panel 200, it should be appreciated that this is simply for relative reference. By way of example, in another embodiment the solder pads 212 may be considered as being on a bottom surface of the lead frame panel 200.

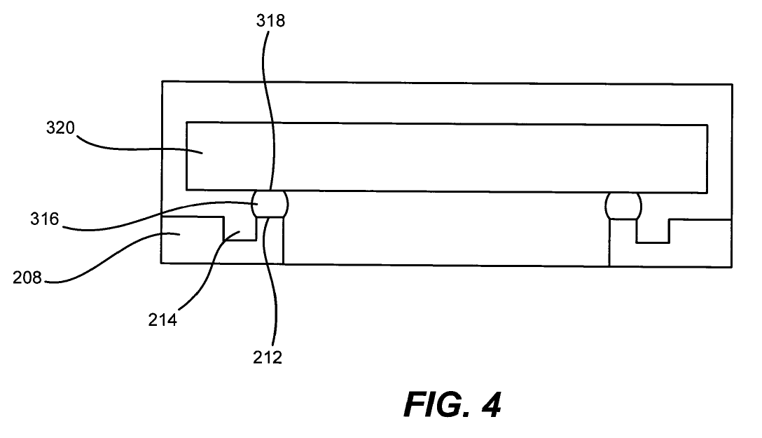

In some embodiments, the spread of solder is controlled at least partially through limiting the spread of flux applied prior to reflow. In general, solder will not spread into areas not prepared with flux. In one embodiment, the flow of flux is limited through the introduction of recessed regions 214 formed adjacent to the solder pads 212. FIG. 3A illustrates a portion of a die package utilizing a lead frame having recessed regions 214. In particular, FIG. 3A illustrates a lead 208 having a conductive solder pad 212. The solder pad 212 is electrically connected to an I/O pad 318 on die 320 via the solder bump 316. A recessed region 214 isolates the solder pad 212 from other surfaces of the lead 208. The recessed regions 214 may be formed by any suitable means. By way of example, the recessed regions 214 may be formed by etching the top surface of the lead frame panel 200. The recessed regions 214 essentially form a moat around each solder pad 212 that serves to isolate the solder pad from the rest of the associated lead surfaces. FIG. 4. illustrates the entire package of FIG. 3A after singulation and encapsulation with a molding material.

As described above, flux is generally applied to the solder bumps 316 and/or the solder pads 212 prior to electrical connection. Each recessed region 214 is recessed sufficiently from the solder pad surface of the associated lead 208 to substantially prevent flux and solder from spreading to undesired surfaces of the lead. More particularly, the recessed regions 214 are preferably etched sufficiently deep such that the spread of flux is limited to the solder pads 212 by the surface tension of the flux. By way of example, the recessed regions 214 are preferably recessed to a depth in the range of approximately 2 to 4 mils in typical lead frame designs although deeper or shallower recessed regions may be provided. Often, recesses that are on the order of one third to one half of the thickness of the leadframe work well. These recess depths work well for a variety of solder pad geometries and sizes.

It should be appreciated that the resulting “raised” solder pads help limit the spread of solder since (a) they tend to define the areas cleaned by flux, and (b) the surface tension of the solder tends to further help prevent the solder from extending beyond the edges of the solder pads 212.

In one embodiment, the recessed regions 214 of the lead frame panel 200 are etched such that the solder pads 212 are substantially circular, as in FIG. 2D. In an alternate embodiment, the solder pads 212 may be substantially oval, rectangular or square (with or without rounded corners). However, in many applications it is preferable to have substantially circular solder pads rather than rectangular solder pads or other solder pads having geometries with sharp corners. More particularly, sharp corners may have the effect of counteracting the forces of surface tension that confine the flux and solder to the surfaces of the solder pads 212. Additionally, in some applications it will be desirable to form solder pads 212 wider than their associated leads 208.

The recessed regions 214 also preferably extend to a sufficient length along the leads 208 so that the flux may not bridge the recessed regions between the solder pads 212 and the rest of the leads 208. By way of example, a recess length in the range of approximately 0.075 to 0.15 mm from the outer edges of the solder pads 212 will work well for many solder pad shapes and sizes. Additionally, in some embodiments it may be desirable for the recessed regions 214 to extend to a greater length. By way of example, it may be desirable for the recessed regions 214 to extend to the package edges or down the entire length of the lead, as illustrated in FIG. 3B.

In other embodiments, the solder pads 212 and I/O pads 318 may be joined in other combinations or by other means. By way of example, solder bumps 316 may be formed on the solder pads 212 first, rather than on the I/O pads 318. Furthermore, a premixed solder paste containing a suitable mixture of both solder and flux may be used to form the solder bumps 316. Regardless of the soldering means, the recessed regions 214 substantially prevent the spread of flux and solder to areas other than the surfaces of the solder pads 212.

It should be appreciated that the present invention may be advantageously used to control the standoff height between the leads 208 and the die 320. As already described, the standoff height between the lead frame (e.g., solder pad 212) and the die (e.g., I/O pad 318) is generally a function of the volume of solder in the solder bump 316 as well as the surface area and geometry of the associated UBM (or I/O pad 318) and solder pad 212. Therefore, by controlling the volume of solder as well as the surface areas and geometries of the solder pad 212 and UBM, a desired standoff height may be achieved. Furthermore, since the same process may be applied to every solder joint, a uniform standoff height may be achieved across the entire die 320. In one embodiment, the surface area of the solder pad 212 is substantially equal to the surface area of the UBM. In other embodiments, it may be desirable for the surface area of the solder pad 212 to be larger than the surface area of the UBM, or vice versa.

Additionally, aspects of the present invention are especially desirable for packages including leads 208 having multiple solder pads 212. It may be desirable for a lead 208 to have two or more solder pads 212 if the lead is to be bonded to two or more equipotential I/O pads 318. By way of example, a single lead 208 may be bonded to multiple power or ground pads. FIG. 3C illustrates a lead 208 having three solder pads 212. Each solder pad 212 is isolated from the other solder pads and from the rest of the lead surfaces by one or more recessed regions 214. Again, the surface tension of the flux keeps the flux and hence the solder confined to the isolated solder pads 212. In this manner, the solder joints 316 remain relatively uniform in shape along the lead 208. Moreover, the separation between the die 320 and lead 208 remains substantially uniform along the length of the lead. As a result, a more uniform standoff height between the die 320 and lead frame should be expected.

Lastly, it may be desirable in some embodiments to recess the opposite surfaces of the leads 208 in portions of the leads corresponding to the solder pads 212, as illustrated in FIG. 3D.

Examples of FCOL packages that may advantageously employ the described lead frames include SOT-23, SC70 and MSOP packages, among many others.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. An integrated circuit package, comprising:
a die, the die including a plurality of I/O pads formed on an active surface thereof;
a lead frame, the lead frame including a multiplicity of leads, wherein a plurality of the leads each have at least one associated solder pad and a contact surface that is distinct from the solder pad, the solder pad being suitably positioned to overlap a corresponding I/O pad on the die, the lead also having a recessed region in a region adjacent the solder pad such that the surface of the solder pad is isolated from other surfaces of the lead;
a plurality of solder bumps, each solder bump being arranged to electrically connect an associated I/O pad to an associated solder pad on the lead frame whereby the solder of each solder bump that contacts an associated lead is confined to the surface of the associated solder pad; and
an encapsulant material that encapsulates the solder bumps and at least portions of the die and leads.

2. A package as recited in claim 1, wherein at least one of the leads includes at least two solder pads isolated from themselves as well as other surfaces of the lead by associated recessed regions.

3. A package as recited in claim 1, wherein widths of the solder pads are wider than their associated leads.

4. A package as recited in claim 1, wherein each recessed region is recessed to a depth in the range of approximately 2 to 4 mils from the surface of the associated solder pad.

5. A package as recited in claim 1, wherein each recessed region extends to a length in the range of approximately 0.075 to 0.15 mm down the length of the associated lead.

6. A package as recited in claim 1, wherein a recessed region extends from the solder pad all of the way down the length of the associated lead.

7. A package as recited in claim 1, wherein portions of the leads are exposed on side surfaces of the package.

8. A package as recited in claim 1, wherein portions of the leads are exposed on a bottom surface of the package.

9. A lead frame panel suitable for use in semiconductor packaging, the lead frame panel comprising a matrix of tie bars that define a plurality of device areas, each device area being configured suitably to support an associated solder bumped die and including:
a multiplicity of leads, wherein a plurality of the leads each have at least one associated solder pad and a contact surface that is distinct from the solder pad, the solder pad being suitably positioned so as to overlap a corresponding I/O pad on a die when the die is suitably positioned adjacent the device area, the lead also having a recessed region in a region adjacent the solder pad such that the surface of the solder pad is isolated from other surfaces of the lead whereby solder from a solder bump on an I/O pad on the die that contacts the lead is confined to the surface of the associated solder pad when the solder is melted.

10. A lead frame panel as recited in claim 9, wherein at least one of the leads includes at least two solder pads isolated from themselves as well as other surfaces of the lead by associated recessed regions.

11. A lead frame panel as recited in claim 9, wherein widths of the solder pads are wider than their associated leads.

12. A lead frame panel as recited in claim 9, wherein each recessed region is recessed to a depth in the range of approximately 2 to 4 mils from the surface of the associated solder pad.

13. A lead frame panel as recited in claim 9, wherein each recessed region extends to a length in the range of approximately 0.075 to 0.15 mm down the length of the associated lead.

14. A lead frame panel as recited in claim 9, wherein a recessed region extends from the solder pad all of the way down the length of the associated lead.

15. A lead frame panel as recited in claim 9, wherein the solder pads are substantially circular.

16. A lead frame panel as recited in claim 9, wherein the solder pads are substantially rectangular.
